(19) United States
(12) Patent Application Publication
(10) Pub. No.: US 2006/0180346 A1
(43) Pub. Date: Aug. 17, 2006

(54) High aspect ratio plated through holes in a printed circuit board

(76) Inventors: Suzanne Knight, Capitola, CA (US); Douglas Thomas, Pacific Grove, CA (US)

Correspondence Address: PERKINS COIE LLP, P.O. BOX 2168, MENLO PARK, CA, 94026, US

(21) Appl. No.: 11/357,503

(22) Filed: Feb. 16, 2006

Related U.S. Application Data
(60) Provisional application No. 60/654,591, filed on Feb. 17, 2005.

(51) Int. Cl. H05K 1/11; H01K 3/10

(52) U.S. Cl. 174/265; 174/266; 29/852; 29/847

(57) ABSTRACT

The drilling and plating of high aspect ratio blind via holes in a multilayer printed circuit board are disclosed. A via hole is drilled through a sub-composite structure. The walls of the via hole are plated with a conductive material, and the hole is filled with a conductive medium. The sub-composite structure proceeds through the remainder of the processing that is necessary to manufacture the printed circuit board up to the completion of the solder mask step. The conductive medium of the via hole is drilled out to achieve a hole size that is of the desired diameter as required by the printed circuit board design.

### CROSS REFERENCE TO RELATED APPLICATION(S)

This application claims the benefit of U.S. Ser. No. 60/654,591 entitled, “Systems and Methods For A Blind Via In A Printed Circuit Board” by inventors, Suzanne Knight and Douglas Thomas, filed Feb. 17, 2005, incorporated herein by reference in its entirety.

### BACKGROUND

Printed circuit boards, backplanes, midplanes, printed wiring boards, flex circuits, rigid flex-circuits, multi-chip modules (MCM), interposers and the like are herein referred to collectively as “PCBs”.

A via structure typically provides a conductive path between conductive layers in the z-axis direction (orthogonal to the x-y plane of a PCB). Via holes are formed by a variety of techniques including but not limited to laser drilling, mechanical drilling, and techniques based on photo definition. Via holes are subsequently partially or wholly filled or coated with a conductive material, usually metal. Such via structures may be blind, buried, through-hole and may or may not include pads on the conductive layers, as is well known to those skilled in the art of PCB design.

Specifically, a blind via hole is an interconnect structure that provides a conductive path between two or more conductive layers in a PCB. One of the two or more conductive layers is an external conductive layer of the PCB. The other conductive layers of the two or more conductive layers are internal layers within the PCB. In other words, a blind via does not extend through all the layers of the PCB.

FIG. 1 is a schematic that illustrates a drilled and plated blind via hole. FIG. 1 shows a laminated PCB 102 comprising conductive layers 104, dielectric layers 106, a blind via hole 108 and a conductive metal 110 palted over via hole 108. In one approach, the via hole of FIG. 1 is drilled by indexing from the surface of laminated PCB 102 and drilling down to the conductive layer 112 to which the blind via 108 is required to connect. Such a blind via should be drilled no further into the PCB than the conductive plane to which the blind is required to connect. Thus, accuracy in drilling is required. Next, a layer of conductive material is deposited on the walls of the blind via hole as part of the normal processing of the PCB.

However, one of the disadvantages of the above approach is that the depth of the via hole that can be formed in the PCB is limited by the aspect ratio of the blind via hole. The aspect ratio of the blind via hole is the ratio of the depth of the blind via hole to the diameter of the blind via hole before any conductive material is deposited in the via hole. The limitation of the aspect raito is due the current approaches of depositing conductive material in the blind via hole in order to make the blind via a conductive interconnect structure between conductive layers of the PCB. For aspect ratios that are greater than 2:1 for small blind vias, currebt deposition approaches are unable to guarantee that a functionally adequate conductive layer will be deposited on the walls of the via hole. This limitation is due to an increased incidence of chemical contamination as the aspect ratio of the blind via hole increases. Further, under conventional plating methods, there is an increased difficulty in gaining adequate thickness in the deposited conductive layer in the via hole due to hole shielding.

Another disadvantage of current approaches of depositing conductive material in blind via holes is that the blind via hole must be accurately drilled down to the desired conductive layer in the PCB to which the blind via is required to connect. In order to ensure that that the blind via hole terminates at the desired conductive layer that the via hole is required to contact, the thickness of dielectric layers above and below the desired conductive layer must be at least 5 mils.

Thus, in view of the foregoing, a plated through hole of a blind via with a high aspect ratio that is greater than 8:1 and that allows for using dielectric layers that have thicknesses less than 5 mils is needed.

### SUMMARY OF EXEMPLARY EMBODIMENTS

In certain exemplary embodiments, a high aspect ratio plated through hole (PTH) or blind via hole in a PCB stackup is made by building a sub-composite structure that includes an external conductive layer and an inner conductive layer in the PCB stackup. The inner conductive layer of the PCB is the conductive layer to which the PTH or blind via hole is required to connect. A via hole is drilled through the sub-composite structure such that the via hole is open at both ends and extending from the external conductive layer through the inner conductive layer.

The walls of the via hole are plated with a conductive material. The plated via hole is then filled with a conductive medium. The sub-composite structure proceeds through the remainder of the processing that is necessary to manufacture the printed circuit board up to the completion of the solder mask step. The conductive medium of the via hole is then drilled out to achieve a hole size that is of the desired diameter as required by the printed circuit board design.

These and other embodiments and other features disclosed herein will become apparent to those of skill in the art upon a reading of the following descriptions and a study of the several figures of the drawing.

### BRIEF DESCRIPTION OF THE DRAWINGS

FIG. 1 is a schematic that illustrates a drilled and plated blind via hole.

FIG. 2 is a schematic of a plated through hole at the initial stages of building a PCB stackup, according to certain embodiments.

FIG. 3 is a schematic of a plated through hole that is filled with a conductive medium, according to certain embodiments.

FIG. 4 is a schematic that illustrates a drilled hole through a conductive medium filling a plated through hole in a PCB, according to certain embodiments.

FIG. 5 is a flowchart that illustrates some high-level steps in making a plated through hole in a PCB, according to certain embodiments.

FIG. 6 is a schematic that shows a plated through hole in a PCB with a connector pin.

FIG. 7 is a schematic that shows a plurality of plated through holes in a PCB stackup.

### DETAILED DESCRIPTION

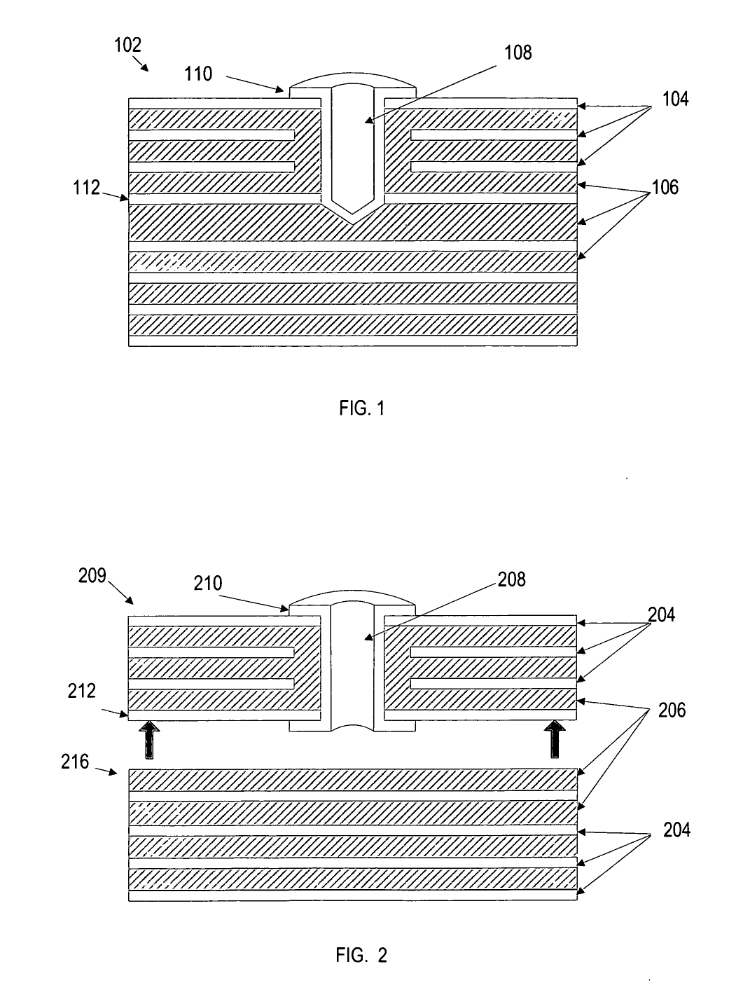

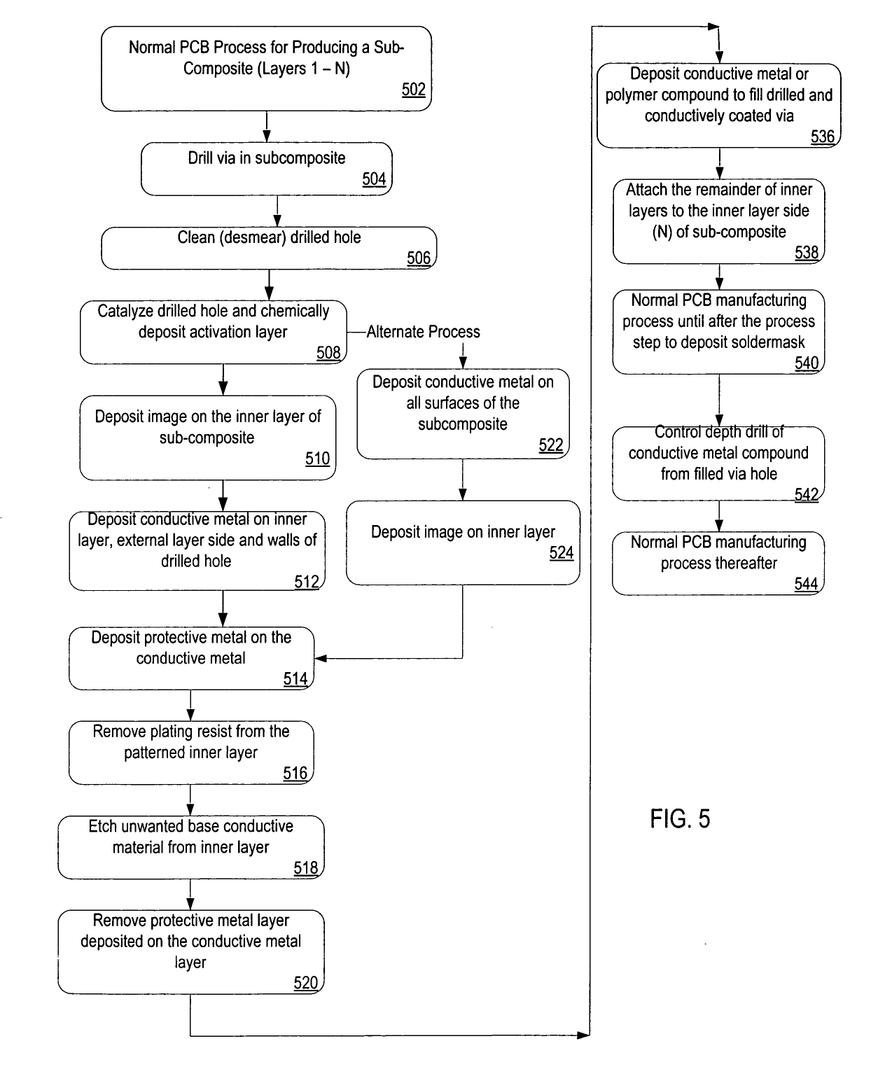

FIG. 2 is a schematic of a plated through hole at the initial stages of building a PCB stackup, according to certain embodiments. Specifically, FIG. 2 shows that a plated blind via of a desired aspect ratio that is greater than 8:1 can be made by first forming a sub-composite structure 209 that comprises conductive layers 204 and dielectric layers 206. A blind via hole is then drilled through the sub-composite layer, extending from the top layer to the bottom layer 212. Bottom layer 212 will subsequently form the inner conductive layer of the PCB after one or more additional laminate structures, such as laminate 216, is added to sub-composite structure 209. The initial stages of building a PCB stackup in the context of making a high aspect plated through hole in the PCB is described in greater detail herein with reference to the flowchart of FIG. 5.

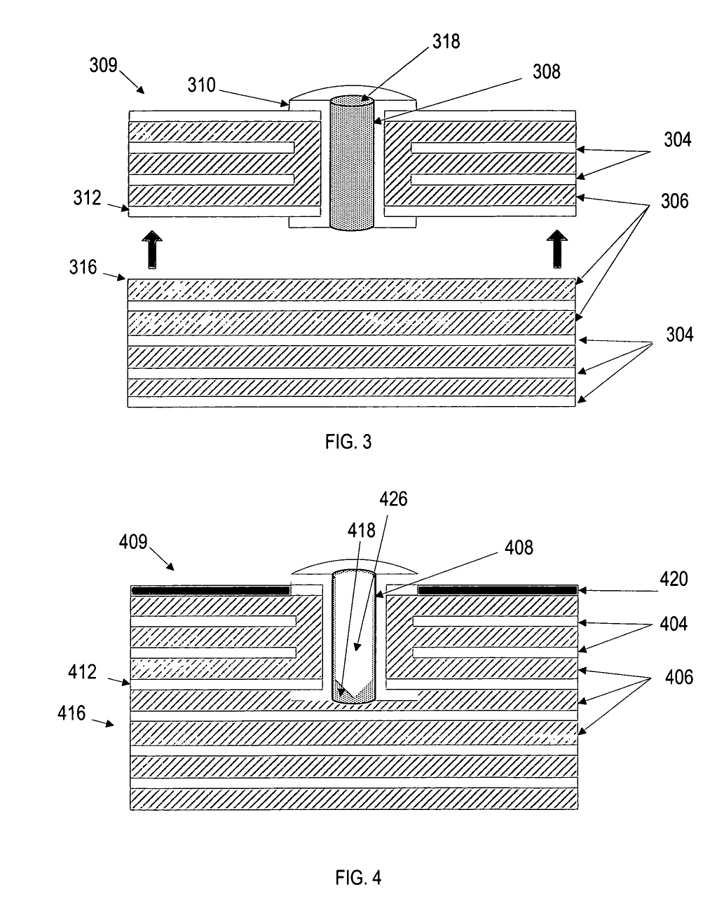

FIG. 3 is a schematic of a plated through hole that is filled with a conductive medium, according to certain embodiments. FIG. 3 shows a sub-composite structure 309 comprising conductive layers 304 and dielectric layers 306. A via hole 308 is drilled through the sub-composite structure 309, extending from the surface of the sub-composite structure through the conductive layer 312. The via hole 308 is plated with a conductive layer 310, after which the via hole 308 is filled with a conductive medium 318. After the via hole 308 is filled with a conductive medium 318, one or more additional cores that make up the PCB, such as laminate 316, is added to sub-composite structure 309. The process of plating and filing the via hole 308 is described in greater detail herein with reference to the flowchart of FIG. 5.

FIG. 4 is a schematic that illustrates a drilled hole through a conductive medium filling a plated through hole in a PCB, according to certain embodiments. FIG. 4 shows sub-composite structure 409 comprising conductive layers 404, and dielectric layers 406. FIG. 4 also shows that a core 416 of the PCB has been added to the sub-composite structure at layer 412 after filing the previously plated hole 408 with a conductive medium 418. After completing the manufacturing of the PCB and applying a layer of solder mask 420 to protect the PCB, the conductive medium 418 is drilled out to form a hole 426. The process of drilling through the conductive medium is described in greater detail herein with reference to the flowchart of FIG. 5.

FIG. 5 is a flowchart that illustrates some high-level steps in making a plated through hole in a PCB, according to certain embodiments. The flowchart of FIG. 5 is not limited to the making of one plated through hole in a PCB. The method described with reference to FIG. 5 may apply to the making of one or more plated through holes in a PCB.

At block 502, a sub-composite structure comprising several layers, such as sub-composite structure 209 of FIG. 2, is made through normal PCB processes. The conductive layers can be copper foil layers or some other suitable conductive layer. The dielectric layers can be layers of prepreg material.

At block 504, a via hole of a desired aspect ratio is drilled through the sub-composite structure. For example, a via hole with an aspect ratio greater than 8:1 is drilled through the sub-composite 209 by indexing from the surface of the sub-composite structure and drilling down to the conductive layer 112 of FIG. 2 to which the via hole is required to connect.

At block 506, the drilled holes are cleaned and desmeared. For example, a chemical process by which the coating of resin that is produced by the heat of drilling is removed from the drilled hole walls and edges of the drilled hole. Additionally, metal burrs and other debris caused by the drilling can be removed and cleaned from the drilled hole.

At block 508, the drilled hole is catalyzed in preparation for deposition of an activation layer. As a non-limiting example, a thin coating of electroless copper is chemically deposited on the surface of the sub-composite structure and on the walls of the drilled hole. Such an activation layer creates a metallic base for subsequent electroplating operations.

At block 510, an image of a desired circuit is deposited on the inner conductive layer, such as conductive layer 212 of FIG. 2. For example, the desired image can be deposited by applying a light sensitive film, using heat and pressure, to the inner conductive layer of the sub-composite structure. The light sensitive film is exposed and developed. Since the drilled hole is to be plated, any film that is tenting the hole is developed off. Areas that are not to be plated are protected by the hardened polymerized resist coat.

At block 512, a layer of conductive material is deposited on the exposed areas of the imaged inner conductive layer, the surface of the external conductive layer and walls of the drilled hole. For example, additional copper is electrically plated through an electroplating process onto the exposed electroless copper surfaces of the sub-composite structure including the walls of the drilled hole.

At block 514, a protective metal is deposited on the exposed electroplated areas of the sub-composite structure. For example, solder or tin-lead can be plated onto the copper plated surfaces.

At block 516, the resist coat described at block 510 is removed from the patterned inner layer of the sub-composite structure. For example, the plating resist can be chemically removed from the patterned inner layer.

At block 518, any unwanted base conductive material is etched away from the patterned inner layer at areas that are not protected by the solder or tin-lead protective layer.

At block 520, the protective metal layer (solder or tin-lead) is removed. For example, the solder or tin-lead is chemically stripped from all the surfaces.

At block 536, the plated via hole, such as hole 308 is filled with a conductive medium, such as conductive medium 318 of FIG. 3. As a non-limiting example, a conductive polymer compound that includes silver is deposited as a paste into the plated hole and then cured. The conductive polymer compound protects the plated through hole against chemical degradation during subsequent manufacturing processes for completing the PCB. Further, the conductive polymer compound fills in any holes or thin spots in the plated copper layer on the walls the via hole.

At block 538, one or more additional cores that make up the PCB stackup, such as core 316 of FIG. 3 is attached to layer 312 of the sub-composite structure 310.

At block 540, normal PCB manufacturing steps are performed until after the process of depositing a layer of soldermask, such as layer 420 of FIG. 4, to the PCB. As a non-limiting example, a photo-sensitive liquid mask, such as probimer, is applied to the surfaces of the PCB.

At block 542, a hole, such as hole 426 of FIG. 4, is controlled drilled, by indexing for example, through the conductive medium, such as conductive medium 418 of FIG. 4, up to a desired depth. At block 544, normal PCB manufacturing processes are followed, thereafter.

As an alternate process, according to certain embodiments, after the process of block 508, a conductive layer is deposited on all exposed surfaces of the sub-composite structure at block 522. Next at block 524, an image of a desired circuit is deposited on the inner conductive layer, such as conductive layer 212 of FIG. 2. Next, control is returned to previously described block 514.

The process as described with reference to FIG. 5 results is the creation pf a blind via hole that can serve as a receptacle for a press fit connector pin as in a connector assembly. Further, the process of FIG. 5 allows blind via holes of a wide variety of aspect ratios to be created with accurate diameter size in order to accommodate many types of press fit connector pins. The accuracy in the diameter size of the blind vias provides improved retention force of the press fit connector pins.

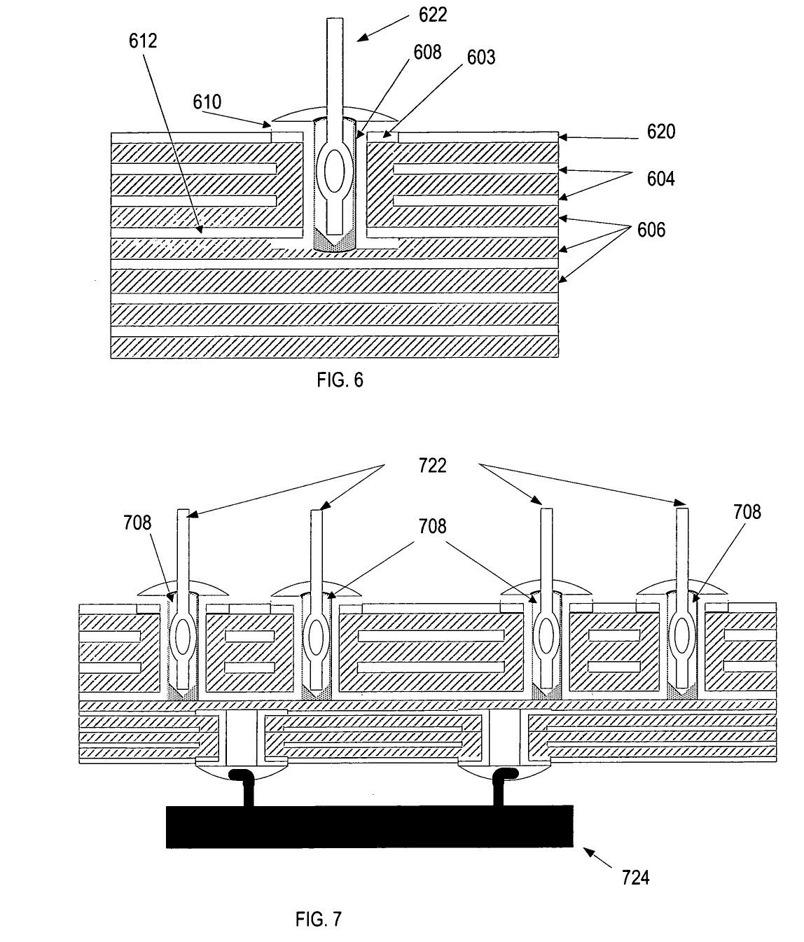

FIG. 6 is a schematic that shows a plated through hole in a PCB with a connector pin. FIG. 6 shows a PCB with soldermask layer 620, conductive layers 604, dielectric layers 606 and plated through hole 608 that connects conductive layer 603 with conductive layer 612. FIG. 6 also shows a connector pin 622 that is inserted into plated through hole 608.

FIG. 7 is a schematic that shows a plurality of plated through holes in a PCB stackup. FIG. 7 shows several plated through holes 708 in which are inserted corresponding connector pins 722. FIG. 7 also shows that the PCB stackup is connected to an electrical component 724.

In the foregoing specification, embodiments of the invention have been described with reference to numerous specific details that may vary from implementation to implementation. The specification and drawings are, accordingly, to be regarded in an illustrative rather than a restrictive sense.

We claim:

1. A method for making a high-aspect ratio plated through hole (PTH) in a PCB stackup, the method comprising:
building a sub-composite structure having a plurality of layers including an external layer and an inner layer relative to said PCB stackup, wherein said inner layer is a layer at which said PTH is designed to terminate;
making a via hole, associated with said PTH, that passes through said sub-composite structure, said via hole being open at both ends and extending from said external layer through said inner layer;
plating a layer of conductive material on walls of said via hole; and
filling said plated via hole with a conductive compound.

2. The method of claim 1, further comprising de-smearing said via hole.

3. The method of claim 1, further comprising catalyzing said via hole and depositing an activation layer on said walls before said plating.

4. The method of claim 1, further comprising depositing a desired circuit image on one or more of said inner layer and said external layer before said plating by using a plating resist material, wherein said desired circuit image exposes areas on one or more of said inner layer and said external layer for said plating.

5. The method of claim 4, further comprising, after depositing said desired circuit image, plating said exposed areas of said inner layer and said external layer when plating said walls of said via hole to form corresponding plated layers on said exposed layers on said inner layer, said external layer and said walls of said via hole.

6. The method of claim 5, further comprising depositing a protective layer on said plated layers.

7. The method of claim 6, further comprising removing said plating resist material from one or more of said inner layer and said external layer.

8. The method of claim 7, further comprising etching away unwanted conductive material from one or more of said inner layer and said external layer.

9. The method of claim 8, further comprising removing said protective layer.

10. The method of claim 1, further comprising curing said conductive compound.

11. The method of claim 1, further comprising laminating said sub-composite structure to one or more of: additional dielectric layers, conductive layers and additional sub-composite structures that make up said PCB stackup.

12. The method of claim 1, further comprising drilling a hole with a diameter as required by a design of said PCB stackup through said conductive compound upon completion of making said PCB stackup.

13. The method of claim 1, wherein said conductive material is metal.

14. The method of claim 1, wherein said conductive material is copper.

15. The method of claim 1, wherein said conductive compound is a polymer compound that includes silver.

16. The method of claim 6, wherein said protective layer is a resist-metal layer.

17. The method of claim 1, wherein an aspect ratio of said via hole before depositing an activation layer and before said plating is greater than 8:1.

18. The method of claim 1, wherein said plated via hole is a conductive path between two or more conductive layers in said PCB stackup.

19. The method of claim 18, wherein at least one conductive layer of said two or more conductive layers is an external conductive layer of said PCB stackup.

20. The method of claim 18, wherein at least one conductive layer of said two or more conductive layers is an internal conductive layer of said PCB stackup.

21. The method of claim 1, further comprising inserting a connector pin in said PTH of said PCB stackup.

22. The method of claim 21, wherein said PCB stackup is any one of a backplane PCB and a midplane PCB.

23. A printed circuit board with at least one plated through hole (PTH), the printed circuit board comprising:
a sub-composite structure having a plurality of layers including an external layer and an inner layer relative to said printed circuit board, wherein said inner layer is a layer at which said at least one PTH is designed to terminate;
a via hole, associated with said at least one PTH, that passes through said sub-composite structure, said via hole being open at both ends and extending from said external layer through said inner layer;
a layer of conductive material on walls of said via hole; and
a conductive compound filled in said via hole.

24. The printed circuit board of claim 23, wherein said conductive compound is cured.

25. The printed circuit board of claim 23, further comprising one or more of: additional dielectric layers, conductive layers and additional sub-composite structures that are laminated to said sub-composite structure and which that make up said printed circuit board.

26. The printed circuit board of claim 23, wherein a hole with a diameter as required by a design of said PCB is drilled into said conductive compound upon completion of making said printed circuit board.

27. The printed circuit board of claim 23, wherein said conductive material is metal.

28. The printed circuit board of claim 23, wherein said conductive material is copper.

29. The printed circuit board of claim 23, wherein said conductive compound is a polymer compound that includes silver.

30. The printed circuit board of claim 23, wherein an aspect ratio of said via hole before plating is greater than 8:1.

31. The printed circuit board of claim 23, wherein said PTH is a conductive path between two or more conductive layers in said printed circuit board.

32. The printed circuit board of claim 31, wherein at least one conductive layer of said two or more conductive layers is an external conductive layer of said printed circuit board.

33. The printed circuit board of claim 31, wherein at least one conductive layer of said two or more conductive layers is an internal conductive layer of said printed circuit board.

34. The printed circuit board of claim 23, further comprising inserting a connector pin in said at least one PTH of said printed circuit board.

35. The printed circuit board of claim 34, wherein said printed circuit board is any one of a backplane printed circuit board and a midplane printed circuit board.
